(19) United States
(12) Patent Application Publication
(10) Pub. No.: US 2011/0207611 A1
(43) Pub. Date: Aug. 25, 2011

(54) SUPERCONDUCTING CABLE WITH ALUMINUM CRYOSTAT

(75) Inventors: Seok Hern Jang, Gunpo-si (KR); Su Kil Lee, Gumi-si (KR); Hyun Man Jang, Hwaseong-si (KR); Chang Youl Choi, Gumi-si (KR); Keun Tae Lee, Busan (KR); Yang Hoon Kim, Jeonju-si (KR)

(73) Assignee: LS CABLE LTD., Anyang-si (KR)

(21) Appl. No.: 13/032,933

(22) Filed: Feb. 23, 2011

(30) Foreign Application Priority Data
Feb. 24, 2010 (KR) 10-2010-0016631

(51) Int. Cl. H01B 12/16; H01L 39/02; F25B 19/00; H01B 12/00

(52) U.S. Cl. 505/163; 62/51.1; 174/125.1

(57) ABSTRACT

Provided is a superconducting cable configured to improve superconductivity by increasing reflectivity of cryostats and enhancing cooling performance. The superconducting cable includes: a core provided with a conductor; and a cryostat surrounding a periphery of the core. A material of the cryostat is aluminum or an aluminum alloy and a surface roughness of the cryostat is 30 microns or less in terms of RMS value.

### CROSS-REFERENCE TO RELATED APPLICATION

This application claims priority to Korean Patent Application No. 10-2010-16631, filed on Feb. 24, 2010, and all the benefits accruing there from under 35 U.S.C. §119, the contents of which in its entirety are herein incorporated by reference.

### BACKGROUND

1. Field

This disclosure relates to a superconducting cable, and more particularly, to a superconducting cable configured to improve superconductivity by increasing reflectivity of cryostats and enhancing cooling performance.

2. Description of the Related Art

In a superconducting cable which can transmit a larger amount of power than existing power cables with a very small loss, a cryostat for maintaining very low temperatures to keep a superconducting wire material in a superconducting state surrounds a superconducting cable core.

FIG. 1 is a conceptual view illustrating a longitudinal cross-section of a superconducting cable according to a related art.

As illustrated in FIG. 1, in a superconducting cable 10, an inner cryostat 12 surrounds a periphery of a core 11 with a gap therebetween, an outer surface of the inner cryostat 12 is taped by a heat insulating layer 13, and an outer cryostat 15 surrounds a periphery of the heat insulating layer 13 with a gap from the heat insulating layer 13. In addition, a spacer 14 is interposed between the outer cryostat 15 and the heat insulating layer 13 to form the gap between the outer cryostat 15 and the heat insulating layer 13.

Here, the space between the inner cryostat 12 and the outer cryostat 15 is maintained in a vacuum state to prevent thermal conduction and radiation, and the heat insulating layer 13 is a film made of a heat insulating material taping an outer surface of the inner cryostat 12 with several layers.

In the superconducting cable configured as described above, the inner cryostat is taped by the heat insulating layer. The heat insulating layer is used for reducing absorption of energy of a particular wavelength into the inner cryostat and enhancing reflection toward outside. The heat insulating layer has excellent surface roughness for reflecting radiated heat energy.

However, even when such a heat insulating layer with excellent surface roughness is formed, it absorbs radiated heat of 3 W/m or more.

When radiated heat energy of 3 W/m or more is absorbed per unit length as described above, the capacity of a cooling system of the superconducting cable has to be increased, and this results in a decreased efficiency and a load increase.

In addition, a thickness of the heat insulating layer needs to be increased, and thus cost is increased due to the increased need of the heat insulating layer, so that there are problems in that the space maintained in vacuum is reduced and a diameter of the spacer is reduced due to the increase in thickness of the heat insulating layer.

### SUMMARY

This disclosure provides a superconducting cable configured to improve superconductivity by reducing absorbance of radiated heat energy of cryostats.

In one aspect, there is provided a superconducting cable including: a core provided with a conductor; and a cryostat surrounding a periphery of the core, wherein a material of the cryostat is aluminum or an aluminum alloy and a surface roughness of the cryostat is 30 microns or less in terms of RMS value.

The cryostat may include an inner cryostat surrounding the periphery of the core and an outer cryostat surrounding a periphery of the inner cryostat with a gap, and a heat insulating layer may be positioned on the periphery of the inner cryostat.

The cryostat may have a corrugated structure, a surface roughness of a concave part of the corrugated structure may be 15 microns or less in terms of RMS value, and a surface roughness of a convex part of the corrugated structure may be 30 microns or less in terms of RMS value.

The cryostat may be manufactured by a hot extrusion method through an extrusion die, and an extrusion angle of the extrusion die may be in the range of 45° to 60°.

The extrusion die may be manufactured from Fe—Cr cast iron or Fe—Ni—Cr cast iron and may have a surface roughness of 5 microns or less in terms of RMS value.

An outlet temperature of the extrusion die may be in the range of 470 to 555° C.

An extrusion speed at which the extrusion die performs extrusion may be in the range of 5 to 10 inch/min.

The superconducting cable according to this disclosure can manage the surface roughness of the aluminum-based unsealed cryostats, so that radiated heat energy permeating from the outside can be minimized and thus superconductivity can be enhanced.

In addition, the cryostat of the superconducting cable according to the disclosure has excellent surface roughness, so that surface abrasion of the heat insulating layer can be minimized when the cryostat is rubbed against the heat insulating layer. There is an advantage in that as the surface of the heat insulating layer is excellent, permeation of the radiated heat energy can be minimized.

In addition, the superconducting cable according to the disclosure uses the cryostats manufactured by the hot extrusion method from pure aluminum or an aluminum alloy, so that there is an advantage in that productivity of the cryostats is excellent. In addition, during the hot extrusion, an oxide film is formed on the cryostat, and this further enhances the surface roughness.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a conceptual view illustrating a longitudinal cross-section of a superconducting cable according to a related art; and

FIGS. 2 and 3 show cross-sectional views of dies used for a manufacturing process in which cryostats are subjected to hot extrusion.

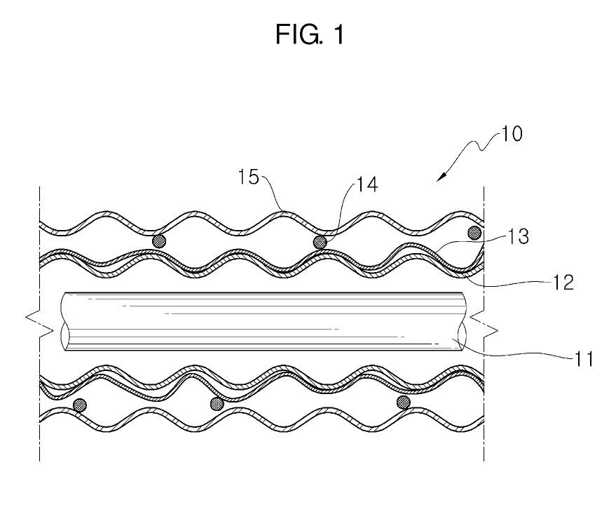

### DETAILED DESCRIPTION

Exemplary embodiments now will be described more fully hereinafter with reference to the accompanying drawings, in which exemplary embodiments are shown. This disclosure may, however, be embodied in many different forms and should not be construed as limited to the exemplary embodiments set forth therein. Rather, these exemplary embodiments are provided so that this disclosure will be thorough and complete, and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The shape, size and regions, and the like, of the drawing may be exaggerated for clarity.

Hereinafter, exemplary embodiments of a superconducting cable will be described in detail with reference to the accompanying drawings.

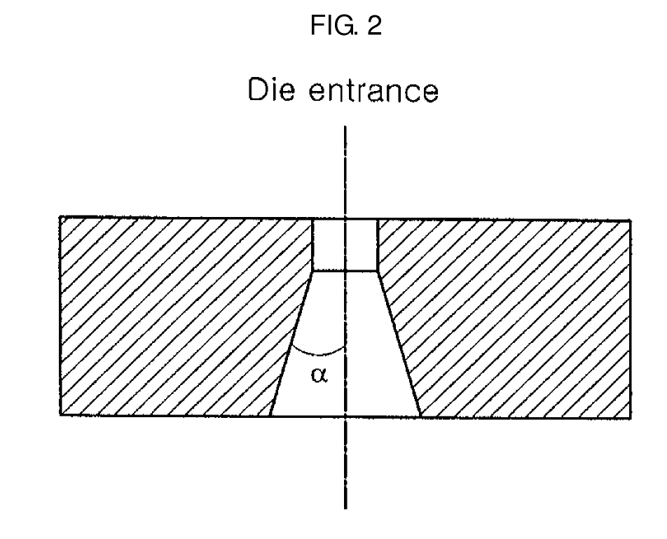

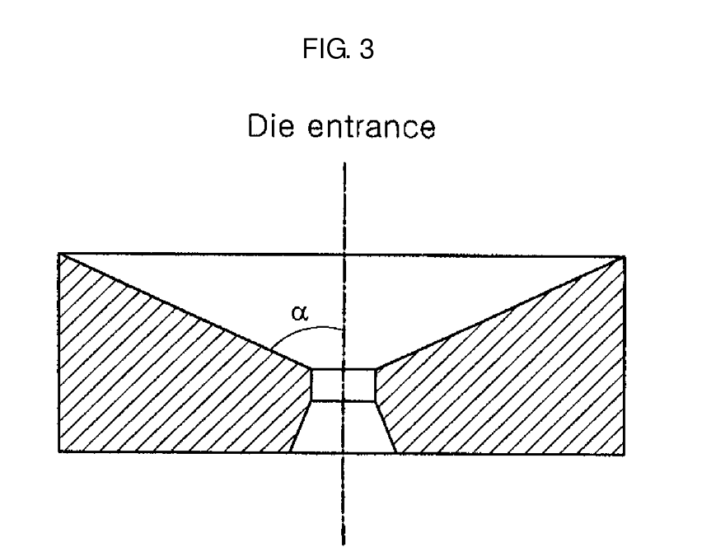

FIGS. 2 and 3 show cross-sectional views of dies used for a manufacturing process in which cryostats are subjected to hot extrusion.

The superconducting cable according to this embodiment has a core positioned therein. An inner cryostat surrounds a periphery of the core, and a heat insulating tape surrounds a periphery of the inner cryostat to form a heat insulating layer. In addition, an outer cryostat surrounds a periphery of the heat insulating layer.

In the superconducting cable configured as described above, the inner cryostat is manufactured by a hot extrusion method from 100 series aluminum of purity 99% or higher or Al—Zn alloys such as A1050, A1100, A2017, A2014, A3003, A3004, A5052, A5N01, A5083, A6061, A6N01, A6063, A7003, and A7075 (hereinafter, collectively referred to as “aluminum”).

Since the inner cryostat is manufactured by the hot extrusion method, a welded site is not formed in the inner cryostat. The existing inner cryostat is formed by bending stainless steel into a circular shape, welding bent end parts, and grinding the welded sites to smooth the surface thereof. However, since the inner cryostat according to this embodiment is manufactured by the hot extrusion method, welding and grounding operations are not needed, and this ensures excellent productivity and workability. The hot-extruded inner cryostat is molded into a corrugated inner cryostat through a corrugation manufacturing process.

Here, a surface roughness of the inner cryostat should be 30 microns or less in terms of RMS value. More particularly, in the corrugated inner cryostat, the surface roughness of a concave part should be 15 microns or less in terms of RMS value, and the surface roughness of a convex part should be 30 microns or less in terms of RMS value.

When the surface roughness of the inner cryostat exceeds 30 microns, radiated heat energy of 3 W/m or more per unit length permeates therethrough. When the surface roughness is less than 30 microns, radiated heat energy of only 1.5 to 2.5 W/m permeates therethrough, thereby minimizing the permeation of the radiated heat energy.

I order to perform the hot extrusion to allow the surface roughness of the aluminum-based inner cryostat to be less than 30 microns, a pressure of 300 to 1,500 tons is applied for extrusion in a vertical direction, and a pressure of 200 to 3,000 tons is applied for extrusion in a horizontal direction.

Specifically, as a billet length is decreased during the extrusion of the aluminum, an extrusion force is reduced due to a decrease in friction area with a container wall. Right before the completion of the extrusion, a deformation resistance of the aluminum flow increases rapidly, and thus the extrusion force is increased. That is, in order to maintain a constant extrusion force along the length of the billet and to accommodate operational conditions such as types of alloys, extrusion ratio, product shapes and billet length and temperature in general-purpose ranges, the applied pressure in the case of vertical direction is 300 to 1,500 tons and the applied pressure in the case of horizontal direction is 200 to 3,000 tons.

The extrusion speed is in the range of 5 to 10 inch/min for improving surface roughness of the aluminum and ensuring extrusion quality. In a case where the extrusion speed is below 5 inch/min, the extrusion pressure is reduced due to the reduction in frictional force between the billet and the container, and the extrusion temperature is decreased below an extrusion temperature range set as a lower limit due to an extrusion time delay. In addition, the deformation resistance of the material is increased due to the extrusion temperature decrease, and thus the temperature is increased again. Consequently, the extrusion texture is changed with the progress of extrusion. On the other hand, in a case where the extrusion speed exceeds 10 inch/min, the extrusion temperature is increased due to the extrusion pressure, and thus defects may occur in the extrusion texture.

The extrusion temperature during the extrusion may be maintained so that an extrusion outlet temperature in the air is in the range of 470 to 555° C.

The temperature range of 470 to 555° C. is a soluble temperature range of the aluminum allowing to dissolve alloy components added to aluminum in an aluminum matrix, and thus is a temperature range for maintaining the texture after extrusion in a uniform state.

As the extrusion die used for the extrusion, a die made of Fe—Cr cast iron or Fe—Ni—Cr cast iron and having a surface roughness of 5 microns or less in terms of RMS value is used.

The Fe—Cr cast iron or the Fe—Ni—Cr cast iron which is the material of the extrusion die is a kind of die material having excellent wear resistance and oxidation resistance at high temperature, and the surface roughness of the hot-extruded inner cryostat can achieve 30 microns or less only when the material of the extrusion die has a surface roughness of 5 microns or less.

Types of the extrusion die are classified into a planar die and a conical die as illustrated in FIGS. 2 and 3. The planar die (a) and the conical die (b) may have an extrusion angle α of 45 to 60 degrees. Such an extrusion angle minimizes a dead zone which is an abnormal aluminum texture that may occur on the surface of the aluminum material due to friction between the die and the aluminum-based fluid. When the extrusion angle is outside the range of 45 to 60 degrees, the dead zone is widened, and in this case the extrusion die cannot be used for the cryostat of the superconducting cable.

Aluminum and aluminum alloys are extruded using the above-described extrusion equipment. Optionally, lubricating oil may be supplied to the die during extrusion, and the inner cryostat may be polished with 1 to 30 micron abrasive (SiC or Al₂O₃) after the extrusion. After the extrusion, cooling may be performed by water cooling or oil cooling.

After manufacturing the outer cryostat under the same condition as the manufacturing of the inner cryostat described above, the outer cryostat may be mounted in the superconducting cable along with the inner cryostat to be installed.

While the exemplary embodiments have been shown and described, it will be understood by those skilled in the art that various changes in form and details may be made thereto without departing from the spirit and scope of this disclosure as defined by the appended claims.

In addition, many modifications can be made to adapt a particular situation or material to the teachings of this disclosure without departing from the essential scope thereof. Therefore, it is intended that this disclosure not be limited to the particular exemplary embodiments disclosed as the best mode contemplated for carrying out this disclosure, but that this disclosure will include all embodiments falling within the scope of the appended claims.

1. A superconducting cable comprising:
a core provided with a conductor; and
a cryostat surrounding a periphery of the core,
wherein a material of the cryostat is aluminum or an aluminum alloy and a surface roughness of the cryostat is 30 microns or less in terms of RMS value.

2. The superconducting cable according to claim 1,
wherein the cryostat includes an inner cryostat surrounding the periphery of the core and an outer cryostat surrounding a periphery of the inner cryostat with a gap, and
a heat insulating layer is positioned on the periphery of the inner cryostat.

3. The superconducting cable according to claim 1,
wherein the cryostat has a corrugated structure,
a surface roughness of a concave part of the corrugated structure is 15 microns or less in terms of RMS value, and
a surface roughness of a convex part of the corrugated structure is 30 microns or less in terms of RMS value.

4. The superconducting cable according to claim 3,
wherein the cryostat is manufactured by a hot extrusion method through an extrusion die, and
an extrusion angle of the extrusion die is in the range of 45° to 60°.

5. The superconducting cable according to claim 4, wherein the extrusion die is manufactured from Fe—Cr cast iron or Fe—Ni—Cr cast iron and has a surface roughness of 5 microns or less in terms of RMS value.

6. The superconducting cable according to claim 4, wherein an outlet temperature of the extrusion die is in the range of 470 to 555° C.

7. The superconducting cable according to claim 4, wherein an extrusion speed at which the extrusion die performs extrusion is in the range of 5 to 10 inch/min.

8. The superconducting cable according to claim 2,
wherein the cryostat has a corrugated structure,
a surface roughness of a concave part of the corrugated structure is 15 microns or less in terms of RMS value, and
a surface roughness of a convex part of the corrugated structure is 30 microns or less in terms of RMS value.
